(19) United States
(12) Patent Application Publication
(10) Pub. No.: US 2021/0215852 A1
(43) Pub. Date: Jul. 15, 2021

(54) POLARIZER PROTECTION FILM, POLARIZING PLATE INCLUDING SAME, AND DISPLAY DEVICE INCLUDING SAID POLARIZING PLATE

(71) Applicant: SAMSUNG SDI CO., LTD., Yongin-si Gyeonggi-do (KR)

(72) Inventors: Ran KIM, Suwon-si (KR); Dae Seob SHIM, Suwon-si (KR)

(21) Appl. No.: 15/999,847

(22) PCT Filed: Feb. 8, 2017
(86) PCT No.: PCT/KR2017/001384

§ 371 Date: Aug. 20, 2018

(30) Foreign Application Priority Data
Feb. 19, 2016 (KR) 10-2016-0019602

(51) Int. Cl. G02B 1/14; B32B 27/30; B32B 27/36; B32B 27/08; G02B 1/04; G02F 1/1335; H01L 27/32

(52) U.S. Cl. CPC G02B 1/14; B32B 27/306; B32B 27/36; B32B 27/08; G02B 1/04; G02F 2202/36; G02F 1/133614; H01L 27/3232; B32B 2255/10; B32B 2457/202; B32B 2307/42; G02F 1/133528

(57) ABSTRACT

A polarizer protective film, a polarizing plate including the same, and a display device including the polarizing plate are provided. In the polarizer protective film, when a refractive index in an in-plane slow axis direction is defined as nₓ and a refractive index in an in-plane fast axis direction is defined as n_{y}, an (nₓ−n_{y}) value is in a range of about 0 to less than about 0.01.

### TECHNICAL FIELD

The present disclosure relates to a polarizer protective film, a polarizing plate including the same, and a display device including the polarizing plate.

### BACKGROUND ART

In a liquid crystal display device or an organic electroluminescent element, transmitted light is optically modulated according to an input image signal, or a luminance pixel according to an image signal is caused to be self-luminous such that a gray scale is obtained for each pixel. A layer in which transmitted light or emission luminance is modulated for each pixel is referred to as a modulation function layer. A liquid crystal layer corresponds to the modulation function layer in the liquid crystal display device, and an organic electroluminescent (EL) emission layer corresponds to the modulation function layer in the organic electroluminescent element.

The liquid crystal layer itself is not a light valve that completely blocks light. Thus, in the case of the liquid crystal display device, a polarizing plate may be disposed at either side of the liquid crystal layer in a vertical direction, i.e., at a backlight side and a viewer viewing side.

Since the emission layer of the organic electroluminescent element does not radiate light when a voltage is not applied thereto, a perfect black color may be displayed, and a relatively high contrast may be provided in comparison to the liquid crystal display device. Accordingly, a polarizing plate is not disposed for the purpose of shielding light emission in the organic electroluminescent element. However, in the case of the organic electroluminescent element, since external light may be reflected by an internal metal wire, and the reflection becomes a cause of contrast degradation, a polarizing plate is disposed to prevent the contrast degradation.

### DISCLOSURE

### Technical Problem

It is an object of the present disclosure to provide a polarizer protective film which is thin and has high mechanical strength and moisture permeability, a polarizing plate including the same, and a display device including the polarizing plate.

It is another object of the present disclosure to provide a polarizer protective film capable of preventing rainbow mura, a polarizing plate including the same, and a display device including the polarizing plate.

Objects of the present disclosure are not limited to the above-mentioned objects, and other unmentioned objects should be clearly understood by one of ordinary skill in the art from the descriptions below.

### Technical Solution

In a polarizer protective film according to an embodiment of the present disclosure for achieving the above-mentioned objects, when a refractive index in an in-plane slow axis direction is defined as nₓ and a refractive index in an in-plane fast axis direction is defined as n_{y}, an (nₓ−n_{y}) value is in a range of about 0 to less than about 0.01.

A thickness of the polarizer protective film may be in a range of about 10 μm to about 45 μm.

The polarizer protective film may include a polyester-based material.

The polarizer protective film may be a copolymer including polyethylene terephthalate, polyethylene naphthalate, or a combination thereof.

The polarizer protective film may be a triple coextruded structure including the copolymer including polyethylene terephthalate, polyethylene naphthalate, or a combination thereof.

A polarizing plate according to an embodiment of the present disclosure for achieving the above-mentioned objects includes a polarizer including polyvinyl alcohol-based resin, and a polarizer protective film laminated to at least one surface of the polarizer, wherein, in the polarizer protective film, when a refractive index in an in-plane slow axis direction is defined as nₓ and a refractive index in an in-plane fast axis direction is defined as n_{y}, an (nₓ−n_{y}) value is in a range of about 0 to less than about 0.01.

A thickness of the polarizer protective film may be in a range of about 10 μm to about 45 μm.

The polarizer protective film may include a polyester-based material.

The polarizer protective film may be a copolymer including polyethylene terephthalate, polyethylene naphthalate, or a combination thereof.

The polarizer protective film may be a triple coextruded structure including the copolymer including polyethylene terephthalate, polyethylene naphthalate, or a combination thereof.

The polarizing plate may further include a function layer disposed at one surface of the polarizer protective film, and the function layer may include one or more of a hard-coating layer, an anti-reflection layer, an anti-glare layer, and a diffusion layer.

A display device according to an embodiment of the present disclosure for achieving the above-mentioned objects includes a display panel configured to display an image according to a signal applied thereto, and one or more polarizing plates disposed on at least one surface of the display panel, wherein the one or more polarizing plates include a polarizing plate of the present disclosure.

The display device may further include a backlight unit configured to provide light to the display panel, the display panel may be formed of a liquid crystal cell, the polarizing plates may include an upper polarizing plate disposed above the liquid crystal cell and a lower polarizing plate disposed below the liquid crystal cell, and a polarizer protective film may be disposed at a viewing side of the upper polarizing plate.

The display panel may further include a quantum dot sheet disposed between the backlight unit and the display panel, wherein the quantum dot sheet includes a quantum dot material.

The display panel may be formed of an organic electroluminescent display panel, the polarizing plates may be disposed at a viewing side of the organic electroluminescent display panel, and a polarizer protective film may be disposed at a viewing side of the polarizing plates.

The display panel may further include a quantum dot sheet disposed at a viewing side of the polarizing plates, wherein the quantum dot sheet includes a quantum dot material.

Details of other embodiments are incorporated in the detailed descriptions and the accompanying drawings.

### Advantageous Effects

Embodiments of the present disclosure have at least the following advantageous effects.

A polarizer protective film, a polarizing plate including the same, and a display device including the polarizing plate of the present disclosure have high mechanical strength and moisture permeability and can prevent generation of rainbow mura.

Advantageous effects according to the present disclosure are not limited to those mentioned above, and various other advantageous effects are incorporated herein.

### DESCRIPTION OF DRAWINGS

FIG. 1 is a cross-sectional view of a polarizer protective film according to an embodiment of the present disclosure.

FIG. 2 is a cross-sectional view of a polarizing plate according to an embodiment of the present disclosure.

FIG. 3 is a cross-sectional view of a polarizing plate according to another embodiment of the present disclosure.

### BEST MODE OF THE INVENTION

Advantages and features of the present disclosure and a method of achieving the same should become clear with embodiments described in detail below with reference to the accompanying drawings. However, the present disclosure is not limited to embodiments disclosed below and is realized in various other forms. The present embodiments make the disclosure of the present disclosure complete and are provided to completely inform one of ordinary skill in the art to which the present disclosure pertains of the scope of the invention. The present disclosure is defined only by the scope of the claims.

When it is mentioned that a certain element or layer is “on” another element or layer, this includes both a case in which the certain element or layer is right above the other element or layer and a case in which another element or layer is interposed therebetween. Like reference numerals refer to like elements throughout.

Terms including ordinals such as first and second may be used to describe various elements, but the elements are not limited by the terms. The terms are only used for the purpose of distinguishing one element from another element. Accordingly, a first element mentioned below may also be referred to as a second element within the technical idea of the present disclosure.

Unless steps that constitute a manufacturing method described herein are stated as being sequential or continuous or are particularly mentioned otherwise, one step and another step constituting a single manufacturing method are not limitedly interpreted according to an order described herein. Therefore, an order of the steps of the manufacturing method may be changed within the scope that is easily understandable by one of ordinary skill in the art, and in this case, such changes which are obvious to one of ordinary skill in the art belong to the scope of the present disclosure.

Polarizer Protective Film

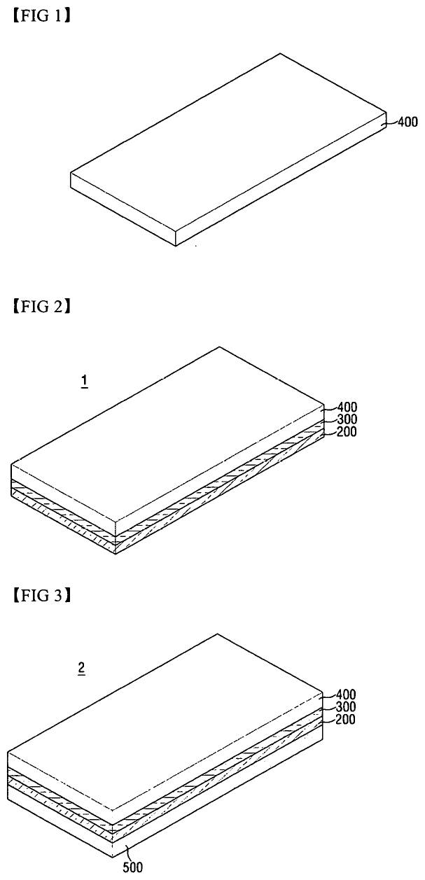

FIG. 1 is a cross-sectional view of a polarizer protective film according to an embodiment of the present disclosure. Referring to FIG. 1, in a polarizer protective film 400, when a refractive index in a slow axis direction is defined as nₓ and a refractive index in a fast axis direction is defined as n_{y}, an (nₓ−n_{y}) value is in a range of about 0 to less than about 0.01. Specifically, the (nₓ−n_{y}) value may be about 0, 0.001, 0.002, 0.003, 0.004, 0.005, 0.006, 0.007, 0.008, 0.009 or less than 0.01. The (nₓ−n_{y}) value may be in a range equal to or greater than about one of the above-listed numerical values and less than or equal to about another numerical value listed above. For example, the (nₓ−n_{y}) value may be in a range of about 0.001 to about 0.009 or in a range of about 0.002 to about 0.007. By the (nₓ−n_{y}) value satisfying the above range, rainbow mura may be prevented from being seen from the outside.

The slow axis may be defined as a direction in which an in-plane refractive index of the polarizer protective film 400 is the maximum, and the fast axis may be defined as a direction perpendicular to the slow axis on a plane.

Generally, when the fast axis of the polarizer protective film 400 is Θᵣ and an absorption axis is Θₚ, when a (Θᵣ₋ₚ) value is not about 90° or about 0°, that is, when the slow axis r of the polarizer protective film 400 and the absorption axis Θp of the polarizer are not perpendicular (about 90°) or parallel (about 0°), rainbow mura is seen by the eyes due to an influence of phase difference birefringence. When the polarizer protective film of the present disclosure is disposed at an end in a viewing direction, rainbow mura may not be seen regardless of the (Θᵣ₋ₚ) value.

Meanwhile, a thickness of the polarizer protective film 400 may be about 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, or 45 μm. Also, the thickness of the polarizer protective film 400 may be in a range equal to or greater than about one of the above-listed numerical values and less than or equal to about another numerical value listed above. Specifically, the thickness of the polarizer protective film 400 may be in a range of about 10 μm to about 45 μm and, for example, may be in a range of about 20 μm to about 45 μm or about 30 μm to about 40 μm. By the thickness of the polarizer protective film 400 satisfying the above range, rainbow mura may be prevented from being seen from the outside. Also, in the above thickness range, a thickness of a polarizing plate may be further reduced.

The polarizer protective film 400 may include a polyester-based material.

Examples of the polyester include dicarboxylic acid such as terephthalic acid, isophthalic acid, orthophthalic acid, 2,5−naphthalene dicarboxylic acid, 2,6-naphthalene dicarboxylic acid, 1,4−naphthalene dicarboxylic acid, 1,5−naphthalene dicarboxylic acid, diphenylcarboxylic acid, diphenoxyethane dicarboxylic acid, diphenylsulfonic carboxylic acid, anthracene dicarboxylic acid, 1,3-cyclopentane dicarboxylic acid, 1,3-cyclohexane dicarboxylic acid, 1,4-cyclohexane dicarboxylic acid, hexahydroterephthalic acid, hexahydroisophthalic acid, malonic acid, dimethyl malonic acid, succinic acid, 3,3-diethyl succinic acid, glutaric acid, 2,2-dimethyl glutaric acid, adipic acid, 2-methyladipic acid, trimethyladipic acid, pimelic acid, azelaic acid, dimer acid, sebacic acid, suberic acid, and dodecadicarboxylic acid, and diol such as ethylene glycol, propylene glycol, hexamethylene glycol, neopentyl glycol, 1,2-cyclohexane dimethanol 1,4-cyclohexane dimenthanol, decamethyleneglycol, 1,3-propanediol, 1,4-butanediol, 1,5-pentanediol, 1,6-hexanediol, 2,2-bis(4-hydroxyphenyl) propane, and bis(4-hydroxyphenyl) sulfone, but are not limited thereto.

Examples of the polyester-based material include a homopolymer obtained by polycondensation of each above mentioned materials, a copolymer obtained by polycondensation of one or more dicarboxylic acids and two or more diols, a copolymer obtained by polycondensation of two or more dicarboxylic acids and one or more diols, and a blend resin obtained by blending two or more of the homopolymers or the copolymers.

In an exemplary embodiment, from the viewpoint that polyester exhibits crystallinity, aromatic polyester may be used. Examples of aromatic polyester may include a copolymer including polyethylene terephthalate (PET), polyethylene naphthalate (PEN), or a combination thereof, but the examples are not limited thereto.

In addition, the polarizer protective film 400 may be a triple coextruded structure including a copolymer resin including PET, PEN, or a combination thereof.

For example, a polyester film is obtained by a method in which the above-mentioned polyester resin is melted and extruded in the form of a film and then cooled and solidified using a casting drum so that the film is formed.

The polarizer protective film 400 is biaxially stretched, more specifically, stretched in an MD direction and stretched in a TD direction. A stretch ratio in the MD direction of the polarizer protective film 400 of the present disclosure and a stretch ratio in the TD direction thereof may be at substantially equivalent levels. Accordingly, a contraction percentage may be controlled for each direction. The stretch ratio in the MD direction of the polarizer protective film 400 may be in a range of about 3 times to about 3.5 times, and the stretch ratio in the TD direction thereof may be in a range of about 2.5 times to about 4 times.

A stretching method is not particularly limited, and a lengthwise-breadthwise successive biaxial stretching method, a lengthwise-breadthwise simultaneous biaxial stretching method, or the like may be adopted as the stretching method. In an exemplary embodiment, stretching may be performed using the simultaneous biaxial stretching method, but embodiments are not limited thereto. Any suitable stretcher such as a roll stretcher, a tenter stretcher, or a pantograph type or linear motor type biaxial stretcher may be used as a stretcher, but embodiments are not limited thereto.

Polarizing Plate

FIG. 2 is a cross-sectional view of a polarizing plate according to an embodiment of the present disclosure. Referring to FIG. 2, a polarizing plate 1 includes a polarizer 200 including a polyvinyl alcohol-based resin, and a polarizer protective film 400 laminated to at least one surface of the polarizer 200, wherein the polarizer protective film 400 is the above-described polarizer protective film. That is, in the polarizer protective film 400, when a refractive index in an in-plane slow axis direction is defined as nₓ and a refractive index in an in-plane fast axis direction is defined as n_{y}, an (nₓ−n_{y}) value may be about 0, 0.001, 0.002, 0.003, 0.004, 0.005, 0.006, 0.007, 0.008, 0.009 or less than 0.01. The (nₓ−n_{y}) value may be in a range equal to or greater than about one of the above-listed numerical values and less than or equal to about another numerical value listed above. Specifically, the (nₓ−n_{y}) value may be in a range of about 0 to less than about 0.01, in a range of about 0.001 to about 0.009, or in a range of about 0.002 to about 0.007. A thickness of the polarizer protective film 400 may be about 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, or 45 μm. Also, the thickness of the polarizer protective film 400 may be in a range equal to or greater than about one of the above-listed numerical values and less than or equal to about another numerical value listed above. Specifically, the thickness of the polarizer protective film 400 may be in a range of about 10 μm to about 45 μm and, for example, may be in a range of about 20 μm to about 45 μm or about 30 μm to about 40 μm.

As mentioned above, the polarizer protective film 400 may include a polyester-based material, and may be a copolymer including PET, PEN, or a combination thereof. Also, the polarizer protective film 400 may be a triple coextruded structure including the copolymer including PET, PEN, or a combination thereof. Since these have already been described above in relation to the polarizer protective film, overlapping descriptions will be omitted.

The polarizer 200 is a film capable of converting natural light or polarized light into arbitrary polarized light. Generally, the polarizer 200 may convert natural light or polarized light into specific linear polarized light. Examples of the polarizer 200 may include those obtained by adsorbing a dichroic substance such as iodine or a dichroic dye from a hydrophilic polymer film such as a polyvinyl alcohol-based film, a partially formylated polyvinyl alcohol-based film, and an ethylene-vinyl acetate copolymer-based partially saponified film and stretching the hydrophilic polymer film, and a polyene-based aligned film such as a dehydrated product of polyvinyl alcohol or a dehydrochlorinated product of polyvinyl chloride, but the polarizer 200 are not limited thereto. In an exemplary embodiment, the polarizer 200 may be a polyvinyl alcohol-based film that has a high degree of polarization and contains iodine having high adhesion property to the polarizer protective film 400, but is not limited thereto.

An adhesive layer 300 may be interposed between the polarizer 200 and the polarizer protective film 400 so that the polarizer 200 and the polarizer protective film 400 are laminated to each other by the adhesive layer 300. The adhesive layer 300 may include a water-based adhesive, but embodiments are not limited thereto, and the adhesive layer 300 may also include an ultraviolet hardening type adhesive.

The water-based adhesive may include one or more selected from the group consisting of a polyvinyl alcohol-based resin and a vinyl acetate-based resin or may include a polyvinyl alcohol-based resin having a hydroxyl group, but the water-based adhesive is not limited thereto.

The ultraviolet hardening type adhesive may include an acrylic compound, e.g., acryl, urethane-acryl, and epoxy, but the ultraviolet hardening type adhesive is not limited thereto.

FIG. 3 is a perspective view of a polarizing plate according to another embodiment of the present disclosure. Referring to FIG. 3, a pressure sensitive adhesive layer 500 may be disposed at the other surface of a polarizer 200. Although not separately shown, a heterogeneous film may be disposed at the other surface of the pressure sensitive adhesive layer 500 to facilitate storage and transport of polarizing plates. The pressure sensitive adhesive layer 500 may also be used for the purpose of attaching a polarizing plate to a display panel which will be described below.

Although not separately shown, a primer layer configured to protect the polarizer 200 and improve adhesiveness between the polarizing plate and the display panel may be disposed between the polarizer 200 and the pressure sensitive adhesive layer 500. The primer layer may be formed by a method in which a coating solution, which includes a water-dispersible polymer resin, water-dispersible fine particles, and water, is applied on the polarizer 200 using a bar coating method, a gravure coating method, or the like, and then is dried.

Meanwhile, although not separately shown, according to still another embodiment of the present disclosure, a polarizer protective film may be laminated in a state in which an adhesive layer is interposed between both surfaces of the polarizer. That is, the polarizer protective film, the adhesive layer, the polarizer, the adhesive layer, and the polarizer protective film may be stacked and laminated in that order in a structure, and the pressure sensitive adhesive layer may be disposed on the polarizer protective film, which is disposed at a surface laminated to the display panel, and laminated to the display panel.

Meanwhile, although not separately shown, the polarizing plate according to still another embodiment of the present disclosure may further include a function layer disposed at one surface of the polarizer protective film. The function layer may include one or more of a hard-coating layer, an anti-reflection layer, an anti-glare layer, and a diffusion layer.

More specifically, the function layer may be formed at an opposite surface of one surface of the polarizer protective film, that is, a surface of the polarizer protective film at which the polarizer is disposed. Regarding the function layer, for example, the hard-coating layer may improve moist heat durability of the polarizing plate and prevent a change in dimension of the polarizing plate, the anti-reflection layer may extinguish light incident from the outside and reduce reflection, and the anti-glare layer may induce diffusion and reflection of light incident from the outside and prevent glare.

Display Device

Although not separately shown, the present disclosure may provide a display device including the above-described polarizing plate.

The display device may include a display panel configured to display an image according to a signal applied thereto, and one or more polarizing plates disposed on at least one surface of the display panel.

The display device may be a liquid crystal display device. When the display device is a liquid crystal display device, the display device may further include a backlight unit in addition to the display panel and the polarizing plates. In this case, the display panel may be formed of a liquid crystal cell. Generally, the liquid crystal cell may include two substrates and a liquid crystal layer interposed between the substrates. Generally, a color filter, a counter electrode, and an aligned film may be formed in one of the substrates, and a liquid crystal driving electrode, a wire pattern, a thin film transistor element, an aligned film, and the like may be formed in the other substrate.

In other words, the liquid crystal display device may include a liquid crystal cell, a backlight unit, a lower polarizing plate disposed between the liquid crystal cell and the backlight unit, and an upper polarizing plate disposed at a viewing side of the liquid crystal cell. At least one of the upper polarizing plate and the lower polarizing plate may include the above-described polarizer protective film, and more specifically, the polarizer protective film of the present disclosure may be disposed as a polarizer protective film disposed at a viewing side of the upper polarizing plate. However, embodiments are not limited thereto, and the polarizer protective film of the present disclosure may also be disposed as a polarizer protective film at the backlight side of the lower polarizing plate.

Meanwhile, as described above in relation to the polarizing plate, a function layer may be further disposed at one surface of the polarizer protective film, and the function layer may be disposed at one surface of the polarizer protective film of the upper polarizing plate. That is, the function layer may be disposed at the outermost side surface of the polarizer protective film disposed at the viewing side of the upper polarizing plate.

Examples of operation modes of the liquid crystal cell include a twisted nematic mode or an electrically controlled birefringence mode. Examples of the electrically controlled birefringence mode include a vertical alignment mode, an optically compensated bend (OCB) mode, and an in-plane switching (IPS) modc.

Generally, the backlight unit may include a light source, a light guide plate, and a reflective film. According to the configuration of the backlight, the backlight unit may be arbitrarily classified into a direct type, a side light type, a planar light source type, and the like.

The lower polarizing plate may be interposed between the backlight unit and the liquid crystal cell. In this case, the polarizer of the lower polarizing plate may only transmit light vibrating in a specific direction among light incident from the light source of the backlight unit.

The upper polarizing plate may also be disposed opposite to the backlight of the liquid crystal cell. In this case, the upper polarizing plate may be interposed between other elements of the liquid crystal display device or be disposed at a surface of the liquid crystal display device. Also, when two polarizing plates are disposed with the liquid crystal cell disposed therebetween, transmission axes of polarizers of the polarizing plates may be orthogonal or parallel.

Meanwhile, the display device may further include a quantum dot sheet disposed between the backlight unit and the display panel, wherein the quantum dot sheet includes a quantum dot material.

The quantum dot material refers to a semiconductor nanoparticle which has a size of several nanometers to several tens of nanometers and has a characteristic in which emitted light differs depending on the size of particles due to a quantum quanfinement effect. More specifically, the quantum dot material generates strong light in a narrow wavelength band, and light emitted by the quantum dot material is generated as electrons in an unstable(excited) state fall from the conduction band to the valence band. In this case, the quantum dot material has a property in which light having a short wavelength is generated as the particle size decreases, and light having a longer wavelength is generated as the particle size increases. Therefore, when the size of the quantum dot material is adjusted, it is possible to emit any light in a visible light region of a desired wavelength.

The quantum dot material may include any one nanocrystal of Si-based nanocrystal, II-VI group-based compound semiconductor nanocrystal, III-V group-based compound semiconductor nanocrystal, IV-VI group-based compound semiconductor nanocrystal, and a mixture thereof. The II-VI group-based compound semiconductor nanocrystal may include one or more selected from the group consisting of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTc, HgZnSeS, HgZnSeTe, and HgZnSTe.

The III-V group-based compound semiconductor nanocrystal may include one or more selected from the group consisting of GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, and InAlPAs.

The IV-VI group-based compound semiconductor nanocrystal may include SbTe.

The quantum dot material generates light having a short wavelength as the particle size decreases and generates light having a longer wavelength as the particle size increases. For example, particles having the size in a range of about 55 to 65 □ emit red light, particles having the size in a range of about 40 to 50 □ emit green light, and particles having the size in a range of about 20 to 35 □ emit blue light. Since, as described above, the quantum dot material generates strong light in a narrow wavelength band at a wavelength corresponding to each color according to the particle size, the quantum dot material may improve optical efficiency of the display device. Meanwhile, the display device may be an organic light-emitting diode (OLED) including an organic electroluminescent element. In this case, the display panel may be an organic electroluminescent display panel. The organic electroluminescent display panel may include each pixel, and each of the pixels may include an OLED formed of an organic electroluminescent layer between an anode and a cathode and a pixel circuit configured to independently drive the OLED. The pixel circuit may mainly include a switching thin film transistor (TFT), a capacitor, and a driving TFT. The switching TFT may charge a data voltage in a capacitor in response to a scan pulse, and the driving TFT may control an amount of current supplied to the OLED depending on the data voltage charged in the capacitor. Accordingly, an amount of emitted light of the OLED may be adjusted, and an image may be displayed. Meanwhile, since the organic electroluminescent display panel is widely known in the art, more detailed descriptions thereof will be omitted.

The polarizing plate may be disposed at a viewing side of the organic electroluminescent display panel, and the polarizer protective film may be disposed at the outermost surface of the polarizing plate. That is, the polarizing plate may be attached to a side surface at which a viewer observes an image displayed on the organic electroluminescent display panel, and the polarizer protective film may be disposed at a viewing side at which the viewer observes an image on the polarizing plate. Therefore, contrast degradation due to reflection of light incident from the outside may be prevented.

In the case of the organic electroluminescent display device, when a function layer is disposed at the polarizer protective film, the function layer may be disposed at the viewing side of the polarizer protective film.

Meanwhile, the organic electroluminescent display device may further include a quantum dot sheet disposed at the viewing side of the polarizing plate, wherein the quantum dot sheet includes a quantum dot material, thereby increasing optical efficiency of the organic electroluminescent display device. Since the quantum dot sheet has been described above in relation to the liquid crystal display device, overlapping descriptions will be omitted.

[Modes of the Invention]

Hereinafter, the configuration and action of the present disclosure will be described in further detail using preferred examples of the present disclosure. However, these are merely given as preferred examples of the present disclosure, and the present disclosure should not be limitedly interpreted thereby in any way.

Since content not described in this section may be easily inferred technically by one of ordinary skill in the art, detailed descriptions thereof will be omitted.

### Examples 1 to 4

When a refractive index in an in-plane slow axis direction of a polarizer protective film is defined as nₓ and a refractive index in an in-plane fast axis direction is defined as n_{y}, an (nₓ−n_{y}) value was set as Table 1 below to manufacture the polarizer protective film, the polarizer protective film was applied to a polarizing plate and then attached to a display panel so as to manufacture a liquid crystal panel. The (nₓ−n_{y}) value and thickness of each example are shown in Table 1 below.

### Comparative Examples 1 to 4

The (nₓ−n_{y}) value was set as Table 1 below to manufacture the polarizer protective film, and the polarizer protective film was applied to a polarizing plate and then attached to a display panel so as to manufacture a liquid crystal panel. The (nₓ−n_{y}) value and thickness of each example are shown in Table 1 below.

### Experimental Example

Rainbow mura of the liquid crystal panels of Examples 1 to 4 and Comparative Examples 1 to 4 was observed and is shown in Table 1 below. The rainbow mura evaluation was performed by a visual evaluation. The visual evaluation was performed by varying a front surface and viewing angle of a liquid crystal panel in which the polarizing plate is attached to a display panel and then determining color sense and mura by visual inspection.

TABLE 1

| | nₓ-n_{y} | Thickness (μm) | Rainbow mura |
|---|---|---|---|
| Comparative | 0.012 | 40 | Lv. 5 |
| Example 1 | | | |
| Comparative | 0.011 | 41 | Lv. 4 |
| Example 2 | | | |
| Comparative | 0.010 | 41 | Lv. 4 |
| Example 3 | | | |
| Comparative | 0.010 | 50 | Lv. 5 |
| Example 4 | | | |
| Example 1 | 0.009 | 38 | Lv. 3 |
| Example 2 | 0.008 | 40 | Lv. 3 |
| Example 3 | 0.002 | 40 | Lv. 1 |
| Example 4 | 0.007 | 45 | Lv. 2 |

In the rainbow mura evaluation of Table 1 above, the visual evaluation is divided into levels 1 to 10, and generation of rainbow mura is decreased as the level becomes closer to Lv. 1. Lv. 1 to Lv. 3 indicate levels at which rainbow mura is generated to an extent in which a panel is applicable, and Lv. 4 or higher indicate levels at which rainbow mura is generated to an extent in which the panel is inapplicable.

As shown in Table 1 above, it is confirmed that, while a rainbow mura phenomenon occurred relatively often in the cases of Comparative Examples, rainbow mura was observed to an extent in which the panel is applicable in the cases of examples in which the (nₓ−n_{y}) value satisfies the above-mentioned range.

All of the above-described embodiments are merely illustrative, and different embodiments may be applied in combination with each other.

1. A polarizer protective film wherein, when a refractive index in an in-plane slow axis direction of the polarizer protective film is defined as nₓ and a refractive index in an in-plane fast axis direction thereof is defined as n_{y}, an (nₓ−n_{y}) value is in a range of about 0 to less than about 0.01.

2. The polarizer protective film of claim 1, wherein a thickness of the polarizer protective film is in a range of about 10 μm to about 45 μm.

3. The polarizer protective film of claim 1, wherein the polarizer protective film includes a polyester-based material.

4. The polarizer protective film of claim 3, wherein the polarizer protective film is a copolymer including polyethylene terephthalate, polyethylene naphthalate, or a combination thereof.

5. The polarizer protective film of claim 4, wherein the polarizer protective film is a triple coextruded structure including the copolymer including polyethylene terephthalate, polyethylene naphthalate, or a combination thereof.

6. A polarizing plate comprising:
a polarizer including polyvinyl alcohol-based resin; and
a polarizer protective film laminated to at least one surface of the polarizer,
wherein, in the polarizer protective film, when a refractive index in an in-plane slow axis direction is defined as nₓ and a refractive index in an in-plane fast axis direction is defined as n_{y}, an (nₓ−n_{y}) value is in a range of about 0 to less than about 0.01.

7. The polarizing plate of claim 6, wherein a thickness of the polarizer protective film is in a range of about 10 μm to about 45 μm.

8. The polarizing plate of claim 6, wherein the polarizer protective film includes a polyester-based material.

9. The polarizing plate of claim 8, wherein the polarizer protective film is a copolymer including polyethylene terephthalate, polyethylene naphthalate, or a combination thereof.

10. The polarizing plate of claim 8, wherein the polarizer protective film is a triple coextruded structure including the copolymer including polyethylene terephthalate, polyethylene naphthalate, or a combination thereof.

11. The polarizing plate of claim 6, further comprising a function layer disposed at one surface of the polarizer protective film,
wherein the function layer includes one or more of a hard-coating layer, an anti-reflection layer, an anti-glare layer, and a diffusion layer.

12. A display device comprising:
a display panel configured to display an image according to a signal applied thereto; and
one or more polarizing plates disposed on at least one surface of the display panel,
wherein the one or more polarizing plates include the polarizing plate of claim 6.

13. The display device of claim 12, further comprising a backlight unit configured to provide light to the display panel, wherein:
the display panel is formed of a liquid crystal cell;
the polarizing plates include an upper polarizing plate disposed above the liquid crystal cell and a lower polarizing plate disposed below the liquid crystal cell; and
a polarizer protective film is disposed at a viewing side of the upper polarizing plate.

14. The display device of claim 13, further comprising a quantum dot sheet disposed between the backlight unit and the display panel, wherein the quantum dot sheet includes a quantum dot material.

15. The display device of claim 12, wherein:
the display panel is formed of an organic electroluminescent display panel;
the polarizing plates are disposed at a viewing side of the organic electroluminescent display panel; and
a polarizer protective film is disposed at a viewing side of the polarizing plates.

16. The display device of claim 15, further comprising a quantum dot sheet disposed at a viewing side of the polarizing plates, wherein the quantum dot sheet includes a quantum dot material.
